(19) United States
(12) Patent Application Publication
(10) Pub. No.: US 2011/0030615 A1
(43) Pub. Date: Feb. 10, 2011

(54) METHOD AND APPARATUS FOR DRY CLEANING A COOLED SHOWERHEAD

(75) Inventors: KEVIN GRIFFIN, Livermore, CA (US); Olga Kryliouk, Sunnyvale, CA (US); Jie Su, Santa Clara, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/847,713

(22) Filed: Jul. 30, 2010

Related U.S. Application Data
(60) Provisional application No. 61/231,117, filed on Aug. 4, 2009.

(51) Int. Cl. C23C 16/52; B08B 7/00

(52) U.S. Cl. 118/666; 134/19

(57) ABSTRACT

The present invention generally provides a method and apparatus for cleaning a showerhead of a deposition chamber, such as a metal organic chemical vapor deposition (MOCVD) chamber. In one embodiment, the showerhead is cleaned without exposing the chamber to the atmosphere outside of the chamber (i.e., in situ cleaning). In one embodiment, flow of liquid coolant through a cooling system that is in fluid communication with the showerhead is redirected to bypass the showerhead, and the liquid coolant is drained from the showerhead. In one embodiment, any remaining coolant is flushed from the showerhead via a pressurized gas source. In one embodiment, the showerhead is then heated to an appropriate cleaning temperature. In one embodiment, the flow of liquid coolant from the cooling system is then redirected to the showerhead and the system is adjusted for continued processing. Thus, the entire showerhead cleaning process is performed with minimal change to the flow of coolant through the cooling system.

### CROSS-REFERENCE TO RELATED APPLICATIONS

This application claims benefit of U.S. Provisional Patent Application Ser. No. 61/231,117 (APPM/013779L), filed Aug. 4, 2009, which is herein incorporated by reference.

### BACKGROUND OF THE INVENTION

1. Field of the Invention

Embodiments of the present invention generally relate to a method and apparatus for in situ dry cleaning a cooled showerhead in a deposition chamber. In particular, methods and apparatus are provided for automated showerhead coolant removal and refilling without discontinuing flow from a cooling system.

2. Description of the Related Art

Group III-V films are finding greater importance in the development and fabrication of a variety of semiconductor devices, such as short wavelength light emitting diodes (LED's), laser diodes (LD's), and electronic devices including high power, high frequency, high temperature transistors and integrated circuits. For example, short wavelength (e.g., blue/green to ultraviolet) LED's are fabricated using the Group III-nitride semiconducting material gallium nitride (GaN). It has been observed that short wavelength LED's fabricated using GaN provide significantly greater efficiencies and longer operating lifetimes than short wavelength LED's fabricated using non-nitride semiconducting materials, such as Group II-VI materials.

One method that is used for depositing Group III-nitrides, such as GaN, is metal organic chemical vapor deposition (MOCVD). This deposition method is generally performed in a chamber having a temperature controlled environment to assure the stability of a first precursor gas, which contains at least one element from Group III, such as gallium (Ga). A second precursor gas, such as ammonia (NH₃), provides the nitrogen needed to form a Group III-nitride. The two precursor gases are injected through a showerhead and into a processing volume within the chamber where they mix and move towards a heated substrate in the processing volume. A carrier gas may be used to assist in the transport of the precursor gases towards the substrate. The precursors react at the surface of the heated substrate to form desirable deposition on the surface of the substrate. However, undesirable deposits also form on other chamber components, such as the precursor introducing showerhead, which therefore, must be periodically cleaned. Further, current cleaning methods either fail to adequately clean the deposits on the showerhead or require significant system downtime, further resulting in increased overall costs of production.

Therefore, there is a need for an improved deposition apparatus and process that provide significantly less downtime for chamber maintenance and cleaning.

### SUMMARY OF THE INVENTION

In one embodiment of the present invention, a deposition apparatus comprises a deposition chamber having one or more walls, a temperature controllable showerhead, and a substrate support defining a processing volume therein, a heat source proximate the deposition chamber, a first temperature sensor disposed within the deposition chamber, a first shut-off valve positioned to control flow of coolant into the showerhead from a coolant supply line, a second shut-off valve positioned to control flow of coolant from the showerhead into a coolant return line, a bypass valve in fluid communication with the coolant supply line upstream from the first shut-off valve and in fluid communication with the coolant return line downstream from the second shut-off valve, and a system controller in communication with the first temperature sensor and configured to control operation of the heat source, the first shut-off valve, the second shut-off valve, and the bypass valve.

In another embodiment of the present invention, a process for cleaning a cooled showerhead in a deposition chamber comprises processing a specified number of substrates at a first temperature within the deposition chamber while maintaining the showerhead at a second temperature via flowing coolant through the showerhead, lowering the temperature within the deposition chamber to a third temperature, bypassing coolant flow around the showerhead, draining the coolant from the showerhead, heating the showerhead to a fourth temperature greater than the second temperature, and flowing one or more cleaning gases through the showerhead while maintaining the temperature of the showerhead at the fourth temperature.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, cross-sectional view of a deposition apparatus.

FIG. 2 is a schematic, diagram of a showerhead assembly according to one embodiment of the present invention for use in the deposition apparatus of FIG. 1.

FIG. 3 is a schematic flowchart depicting a process for cleaning the showerhead assembly depicted in FIG. 2.

For clarity, identical reference numerals have been used, where applicable, to designate identical elements that are common between figures. It is contemplated that features of one embodiment may be incorporated in other embodiments without further recitation.

### DETAILED DESCRIPTION

The present invention generally provides a method and apparatus for cleaning a showerhead in a deposition chamber, such as a metal organic chemical vapor deposition (MOCVD) chamber. In one embodiment, the showerhead is cleaned without exposing the interior components of the chamber to the atmosphere outside of the chamber (i.e., in situ cleaning). In one embodiment, flow of liquid coolant through a cooling system that is in fluid communication with the showerhead is redirected to bypass the showerhead, and the liquid coolant is drained from the showerhead. In one embodiment, any coolant remaining after draining the showerhead is flushed from the showerhead via a pressurized gas source. In one embodiment, the showerhead is then heated to an appropriate cleaning temperature. In one embodiment, the flow of liquid coolant from the cooling system is then redirected to the showerhead. Thus, the entire process is performed with minimal change to the flow of coolant through the cooling system.

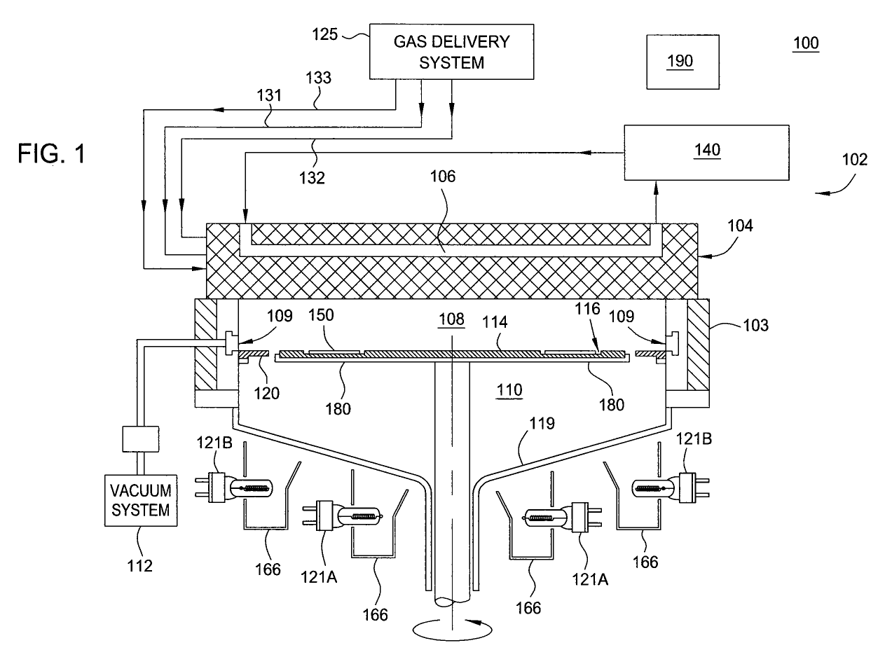

FIG. 1 is a schematic, cross-sectional view of a deposition apparatus 100. The apparatus 100 comprises a chamber 102, a gas delivery system 125, a vacuum system 112, and a cooling system 140. The chamber 102 includes a chamber body 103 that encloses a processing volume 108. A showerhead 104 is disposed at one end of the processing volume 108, and a substrate carrier 114 is disposed at the other end of the processing volume 108. A lower dome 119 is disposed at one end of a lower volume 110, and the substrate carrier 114 is disposed at the other end of the lower volume 110. The substrate carrier 114 is shown in a processing position, but it may be moved to a lower position where, for example, substrates 150 may be loaded or unloaded. An exhaust ring 120 may be disposed around the periphery of the substrate carrier 114 to help prevent deposition from occurring in the lower volume 110 and also to help direct exhaust gases from the chamber 102 to exhaust ports 109. The lower dome 119 may be made of transparent material, such as high-purity quartz, to allow light to pass through for radiant heating of the substrates 150. The radiant heating may be provided by a plurality of inner lamps 121A and outer lamps 121B disposed below the lower dome 119. Reflectors 166 may be used to help control chamber exposure to the radiant energy provided by inner and outer lamps 121A and 121B. Additional rings of lamps may also be used for finer temperature control of the substrates 150.

The substrate carrier 114 may include one or more recesses 116 within which one or more substrates 150 may be disposed during processing. The substrate carrier may be formed from a variety of materials, including silicon carbide or silicon carbide-coated graphite. The substrate carrier 114 may rotate about an axis during processing. Rotating the substrate carrier 114 aids in providing uniform heating of the substrates 150 and uniform exposure of processing gases to each substrate 150 during deposition processes.

The plurality of inner lamps 121A and outer lamps 121B may be arranged in concentric circles or zones, and each lamp zone, and/or one or more lamps in each zone, may be separately powered. In one embodiment, one or more temperature sensors 180, such as pyrometers, may be disposed within the chamber 102 to measure the temperatures within the processing volume 108. The temperature measurement data may be sent to a controller 190, which can adjust power to separate lamp zones based on the measured temperatures to maintain a predetermined temperature profile across the substrate carrier 114. The inner lamps 121A and outer lamps 121B may heat the substrates 150 to a temperature of about 400° C. to about 1200° C. In one embodiment, the substrates 150 are processed at a temperature between about 1000° C. and about 1200° C.

In one embodiment, the showerhead 104 is comprised of a material such as stainless steel, Inconel®, Hastelloy®, electroless nickel plated aluminum, pure nickel, or other metals or alloys resistant to chemical attack. In order to maintain the temperature of the showerhead 104 at an appropriate processing temperature to prevent excessive thermal stresses, a cooling channel 106 within the showerhead 104 is in fluid communication with the cooling system 140, such as a heat exchanger, which circulates a cooling fluid, or coolant, through the showerhead 104. Suitable coolants may include, water, water-based ethylene glycol mixtures, oil-based thermal transfer fluids or similar fluids. In one embodiment, the cooling system 140 maintains the showerhead 104 at a processing temperature between about 80° C. and about 120° C.

The gas delivery system 125 may include multiple gas sources, which are supplied to the showerhead 104 through supply lines 131, 132, 133. The supply lines 131, 132, 133 may supply different gasses, such as precursor gases, carrier gases, purge gases, or cleaning gases to the showerhead 104, from which they flow to form deposition products or to clean chamber components of such deposition products. Precursor gases may include metal organic precursors, such as trimethyl gallium, trimethyl aluminum, or trimethyl indium, among others. Other precursor gases may include nitrogen precursors, such as ammonia. The showerhead 104 separately delivers the gases into the processing volume 108 through a plurality of gas passages (not shown) formed in the showerhead 104.

During typical processing, reaction of the precursor gases at elevated processing temperatures results in the desirable deposition of various metal nitride layers on the substrates 150 as well as undesirable deposition of deposition products on components of the chamber 102 including the surface of the showerhead 104. During continued processing, particles on chamber surfaces formed during prior deposition cycles may flake off and contaminate the substrates 150. Therefore, periodic chamber cleaning is needed to prevent contamination of the substrates 150.

One method of cleaning the chamber 102 and showerhead 104 includes a wet cleaning process that requires exposing the interior of the chamber 102 to atmosphere and therefore results in significant downtime of the entire system. Another cleaning option is a dry cleaning process involving introducing cleaning gases into the chamber 102, in situ, at elevated temperatures, such as between about 400° C. and about 900° C. However, because the flow of coolant from the cooling system 140 through the showerhead 104 maintains the temperature of the showerhead 104 at a temperature significantly below both substrate processing and chamber cleaning temperatures, dry cleaning processes are not currently capable of cleaning the surface of the showerhead 104. Moreover, even if the flow of the coolant through the showerhead 104 is stopped, the mere presence of the cooling fluid within the showerhead 104 prevents such dry cleaning processes because the cooling fluid acts as a thermal sink, requiring significant time to heat the surface of the showerhead 104 to an adequate temperature for performing cleaning processes thereon.

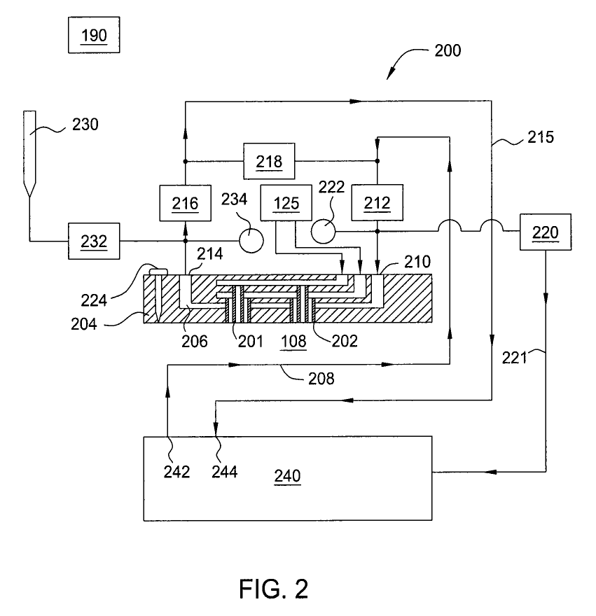

FIG. 2 is a schematic, diagram of a showerhead assembly 200 according to one embodiment of the present invention for use in the deposition apparatus 100. In one embodiment, the showerhead assembly 200 includes a showerhead 204 that separately delivers precursor gases from the gas delivery system 125 through a plurality of gas passage conduits 201, 202 and into the processing volume 108 of the chamber 102 (FIG. 1). In one embodiment, the gas passage conduits 201, 202 are concentric tubes that separately deliver a metal containing precursor and a nitrogen containing precursor into the processing volume 108, such that the two precursors are not mixed until they reach the processing volume 108.

The showerhead 204 has a coolant channel 206 disposed therein. In one embodiment, the coolant channel 206 is an open volume formed in the showerhead 204 for flowing coolant therethrough. In one embodiment, each of the gas passage conduits 201, 202 pass through the coolant channel 206 as schematically depicted in FIG. 2. The coolant channel 206 is in fluid communication with a cooling system 240, such as a heat exchanger. In one embodiment, a coolant supply line 208 supplies coolant from an outlet 242 of the cooling system 240 to an inlet 210 of the coolant channel 206. A coolant supply valve 212 is positioned in line with the coolant supply line 208 between the cooling system 240 and the coolant channel 206 in the showerhead 204. The coolant is returned from an outlet 214 of the coolant channel 206 to an inlet 244 of the cooling system 240 via a coolant return line 215. A coolant return valve 216 is positioned in line with the coolant return line 215 between the coolant channel 206 and the cooling system 240. A coolant bypass valve 218 is positioned between and in fluid communication with the coolant supply line 208 upstream from the coolant supply valve 212 and the coolant return line 215 downstream from the coolant return valve 216.

In one embodiment, a coolant drain valve 220 is positioned in fluid communication with the coolant supply line 208 downstream from the coolant supply valve 212 and is in fluid communication with the cooling system 240 via a coolant drain line 221. In one embodiment, a first pressure switch 222 is positioned in fluid communication with the coolant supply line 208 downstream from the coolant supply valve 212. In one embodiment, a pressurized gas source 230 is in fluid communication with the coolant return line 215 upstream from the coolant return valve 216. A gas control valve 232 is positioned to control the flow of the pressure of the pressurized gas into the coolant return line 215 upstream from the coolant return valve 216. In one embodiment, a second pressure switch 234 is positioned in fluid communication with the coolant return line 215 upstream from the coolant return valve 216 as well.

In one embodiment, the showerhead assembly 200 further includes one or more temperature sensors 224, such as a thermocouple, embedded within the showerhead 204 to accurately measure the temperature of the surface of the showerhead 204 closest to, or facing, the processing volume 108. The temperature data may be sent to a controller 190, which can adjust the level of power supplied to separate lamp zones to maintain a predetermined temperature profile across the surface of the showerhead 204. In one embodiment, the surface of the showerhead 204 may be maintained at a temperature from about 180° C. to about 350° C. during cleaning processes.

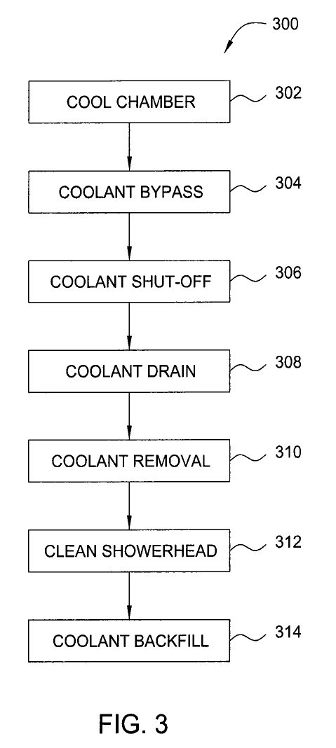

FIG. 3 is a schematic flowchart depicting a process 300 for cleaning the showerhead assembly 200 depicted in FIG. 2 as used in the apparatus 100 depicted in FIG. 1. In one embodiment, the system controller 190 is in communication with each of the valves, sensors, switches, and lamps within the apparatus 100 and the showerhead assembly 200 attached thereto to control cleaning processes described herein. As previously set forth, the substrates 150 are typically processed at a processing temperature between about 1000° C. and about 1200° C., while the showerhead 204 is continuously maintained at a temperature between about 80° C. and about 120° C. by actively cooling the showerhead 204 with the flow of coolant through the coolant channel 206. The temperature of the system during processing is maintained by the system controller 190 in communication with the temperature sensors 180. After a predefined number of processing cycles, the chamber 102 is cleaned by injecting cleaning gases, such as Cl₂, Br, I₂, HCl, HBr, or HI, and maintaining the processing volume 108 at a temperature between about 600° C. and about 900° C. Again, the temperature of the system during chamber cleaning is maintained by the system controller 190 in communication with the temperature sensors 180. However, because the showerhead 204 is maintained at a temperature significantly below the chamber cleaning temperature by the flow of coolant through the coolant channel 206, the showerhead 204 is not adequately cleaned. Therefore, the inventive process 300 is needed for cleaning the showerhead 204 in situ.

After the above-described chamber cleaning process, the process 300 for cleaning the showerhead 204 begins with an initial cooling operation 302 of the processing volume 108. In one embodiment, the processing volume 108 is cooled to below about 450° C. in the initial cooling operation 302. The initial cooling operation 302 may be controlled by the system controller 190 in conjunction with the temperature sensors 180 and the inner and outer lamps 121A and 121B. Once the processing volume 108 has cooled to a predefined temperature, a coolant bypass operation 304 may be performed. In one embodiment of the coolant bypass operation 304, the bypass valve 218 is opened by the system controller 190 to allow a portion of the coolant flow from the coolant supply line 208 to flow to the coolant return line 215 without entering the coolant channel 206 within the showerhead 204. A predefined amount of time is allowed to pass before performing the next operation in order to allow equalization of flow and pressure through the bypass valve 218.

Once equalization of pressure and flow of coolant through the bypass valve 218 has been achieved, flow of coolant into the coolant channel 206 within the showerhead 204 is stopped via a coolant shut-off operation 306 while bypass flow of coolant continues. In one embodiment of the coolant shut-off operation 306, the coolant supply valve 212 is closed. Concurrently, the coolant return valve 216 is closed. The closing of both the coolant supply valve 212 and the coolant return valve 216 shuts off coolant flow from the cooling system 240, and all coolant flow is channeled from the coolant supply line 208 to the coolant return line 215 without entering the showerhead 204. A predetermined amount of time is then allowed to pass in order to equalize coolant flow and pressure across the bypass valve 218.

Once equalization of pressure and flow of coolant through the bypass valve 218 has been achieved, a coolant drain operation 308 is performed to release the coolant in the coolant channel 206 from the showerhead 204. In one embodiment, the coolant drain valve 220 is opened to allow coolant remaining within the coolant channel 206 to drain to the cooling system 240. This operation relieves pressure within the coolant channel 206 and ensures an open drain line from the coolant channel 206 to the cooling system 240. In one embodiment, the system controller 190 performs a check on the first pressure switch 222 to ensure that pressure has been relieved and equalized within the coolant channel 206. In one embodiment, the system controller 190 ensures that the pressure in the coolant channel 206 is below about 60 psi before performing the next operation.

Once the pressure in the showerhead coolant channel 206 is below a sufficiently low pressure, a coolant removal operation 310 is performed to remove any remaining coolant from the coolant channel 206 within the showerhead 204. In one embodiment, the system controller 190 opens the gas control valve 232 to supply a gas, such as clean dry air, at a desired pressure into the coolant channel 206 to forcibly remove any remaining coolant. In one embodiment, gas is supplied into the coolant channel 206 at a pressure between about 70 psi and about 120 psi. In one embodiment, gas is supplied into the coolant channel 206 at a pressure between about 80 psi and about 100 psi. In each instance, the gas is supplied at a pressure exceeding the pressure of the coolant within the coolant channel 206. The gas is allowed to continue flowing for a specified amount of time to ensure that substantially all of the remaining coolant is removed from the showerhead 204. In one embodiment, the system controller 190 performs a safety check on the second pressure switch 234 to ensure that an over-pressure situation does not occur due to any line blockage of valve malfunctions. Once substantially all of the coolant is removed from the showerhead 204, the system controller closes the gas control valve 232.

After substantially all of the coolant is removed from the showerhead 204, a showerhead cleaning operation 312 is performed. In one embodiment, the system controller 190 first switches to provide temperature control based on temperature data received from the one or more temperature sensors 224 in the showerhead 204. Based on this temperature information, the system controller 190 powers the lamps 121A and 121B to control the temperature of the surface of the showerhead 204 at between about 180° C. and about 350° C. during the showerhead cleaning operation 312. In one embodiment, a cleaning gas, such as chlorine, is introduced into the processing volume 108 from the gas delivery system 125 through the showerhead 204. The cleaning gas may be supplied at a rate between about 2 slm and about 8 slm. In one embodiment, the cleaning gas readily reacts chemically with deposits on the surface of the showerhead 204 to form a salt, such as GaCl₃ and NH₄Cl. In one embodiment, the salt is then dissociated and/or sublimated at a higher temperature, such as greater than about 200° C. and removed from the processing volume 108. Thus, the showerhead 204 can be dry cleaned without opening the chamber 102 to atmosphere and performing a wet clean operation as required in prior art processing.

Once the showerhead 204 is cleaned, the showerhead 204 may be refilled with coolant for continued processing of substrates 150 according to a back filling operation 314. In one embodiment, the system controller 190 first sets temperature control to a fixed lamp power, such as between about 3 kW and 7 kW. This locks out any feed back control based on temperature while the back filling operation 314 is being performed. In one embodiment, the coolant drain valve 220 is next closed to prevent draining of coolant from the coolant channel 206 during the back filling operation 314. Next, the coolant supply valve 212 and the coolant return valve 216 are opened to allow coolant from the cooling system 240 to begin flowing back into the coolant channel 206 in the showerhead 204. Next, the bypass valve 218 is closed to prevent coolant from bypassing the coolant channel 206 and ensure full coolant flow through the showerhead 204 to achieve adequate cooling during the next substrate processing cycle. Finally, the system controller 190 changes temperature control back to monitoring the temperature of the first temperature sensors 180 and adjusting the power of the lamps 121A and 121B to ramp up to the desired temperature for processing the next cycle of substrates 150.

Therefore, embodiments of the present invention provide an apparatus and method for in situ dry cleaning of a cooled showerhead within a deposition chamber. In one embodiment, system hardware and processes are provided to remove coolant from the showerhead without interrupting flow from a cooling system. This allows the showerhead to be maintained at an elevated temperature to ensure adequate dry cleaning of deposits left on the showerhead from substrate deposition processes. It has been found that embodiments of the present invention dramatically decrease system downtime for maintenance and cleaning over prior art apparatus and processes. In one embodiment, system downtime for each cleaning cycle was reduced from about 12 hours to about 2 hours. Such dramatic decreases in downtime significantly reduces the overall cost of the system and the production of processed substrates for products such as light emitting diodes, laser diodes, and other electronic devices.

While the foregoing is directed to embodiments of the present invention, other and further embodiments of the invention may be devised without departing from the basic scope thereof, and the scope thereof is determined by the claims that follow.

1. A deposition apparatus, comprising:
a deposition chamber having one or more walls, a temperature controllable showerhead, and a substrate support defining a processing volume therein;
a heat source proximate the deposition chamber;
a first temperature sensor disposed within the deposition chamber;
a first shut-off valve positioned to control flow of coolant into the showerhead from a coolant supply line;
a second shut-off valve positioned to control flow of coolant from the showerhead into a coolant return line;
a bypass valve in fluid communication with the coolant supply line upstream from the first shut-off valve and in fluid communication with the coolant return line downstream from the second shut-off valve; and
a system controller in communication with the first temperature sensor and configured to control operation of the heat source, the first shut-off valve, the second shut-off valve, and the bypass valve.

2. The deposition apparatus of claim 1, further comprising:
a drain line in fluid communication with the coolant supply line downstream from the first shut-off valve; and
a third shut-off valve positioned to control flow of coolant in the drain line.

3. The deposition apparatus of claim 2, wherein the operation of the third shut-off valve is controlled by the system controller.

4. The deposition apparatus of claim 3, further comprising a first pressure sensor in fluid communication with the coolant supply line downstream from the first shut-off valve and in communication with the system controller.

5. The deposition apparatus of claim 4, further comprising a fourth shut-off valve in fluid communication with the coolant return line upstream from the second shut-off valve and positioned to control flow of pressurized gas into the showerhead.

6. The deposition apparatus of claim 5, wherein the operation of the fourth shut-off valve is controlled by the system controller.

7. The deposition apparatus of claim 6, further comprising a second pressure sensor in fluid communication with the coolant return line upstream from the second shut-off valve and in communication with the system controller.

8. The deposition apparatus of claim 7, further comprising a second temperature sensor disposed within the showerhead and in communication with the system controller.

9. A process for cleaning a cooled showerhead in a deposition chamber, comprising:
processing a specified number of substrates at a first temperature within the deposition chamber while maintaining the showerhead at a second temperature via flowing coolant through the showerhead;
lowering the temperature within the deposition chamber to a third temperature;
bypassing coolant flow around the showerhead;
draining the coolant from the showerhead;
heating the showerhead to a fourth temperature greater than the second temperature; and
flowing one or more cleaning gases through the showerhead while maintaining the temperature of the showerhead at the fourth temperature.

10. The process of claim 9, further comprising pressurizing the showerhead to purge remaining coolant from the showerhead prior to heating the showerhead.

11. The process of claim 10, wherein bypassing the coolant flow around the showerhead, comprises:
closing a first shut-off valve configured to control coolant flow to the showerhead;
closing a second shut-off valve configured to control coolant flow from the showerhead; and
opening a bypass valve configured to control coolant flow between a point upstream of the first shut-off valve and a point downstream from the second shut-off valve.

12. The process of claim 11, wherein draining the coolant comprises opening a third shut-off valve configured to control coolant flow from a point downstream of the first shut-off valve.

13. The process of claim 12, wherein pressurizing the showerhead comprises opening a fourth shut-off valve configured to control the flow of pressurized gas into the showerhead.

14. The process of claim 13, wherein the first temperature is between about 1000° C. and about 1200° C.

15. The process of claim 14, wherein the second temperature is between about 80° C. and about 120° C.

16. The process of claim 15, wherein the third temperature is below about 450° C.

17. The process of claim 16, wherein the fourth temperature is between about 180° C. and about 350° C.

18. The process of claim 17, further comprising lowering the temperature within the deposition chamber to between about 600° C. and about 900° C. and introducing cleaning gases into the deposition chamber prior to lowering the temperature in the deposition chamber to the third temperature.
